(19) United States
(12) Patent Application Publication
(10) Pub. No.: US 2022/0290293 A1
(43) Pub. Date: Sep. 15, 2022

(54) HARDWARE AND PROCESSES FOR IN OPERANDO DEPOSITION SHIELD REPLACEMENT/SURFACE CLEANING

(71) Applicant: HelioSource Tech, LLC, Tucson, AZ (US)

(72) Inventors: Walter Seaman, Tucson, AZ (US); Billy Jack Stanbery, Austin, TX (US)

(21) Appl. No.: 17/677,855

(22) Filed: Feb. 22, 2022

Related U.S. Application Data
(60) Provisional application No. 63/161,047, filed on Mar. 15, 2021.

(51) Int. Cl. C23C 14/54; C23C 14/24

(52) U.S. Cl. CPC C23C 14/54; C23C 14/24

(57) ABSTRACT

A method includes operating movable reactor shielding located in a vacuum deposition chamber comprising at least one of operating movable source debris shields and operating movable reactor zone debris shields. An apparatus includes movable reactor shielding located in a vacuum deposition chamber, the movable reactor shielding comprising at least one of movable source debris shields and movable reactor zone debris shields.

### CROSS-REFERENCE TO RELATED APPLICATION

Referring to the application data sheet filed herewith, this application claims a benefit of priority under 35 U.S.C. 119(e) from co-pending provisional patent application U.S. Ser. No. 63/161,047, filed Mar. 15, 2021, the entire contents of which are hereby expressly incorporated herein by reference for all purposes.

### BACKGROUND

Current methods of in-line evaporated thin film solar materials are limited in deposition rate and/or run time due to gas scattering and debris generation. In co-deposition environments, mixing of the various evaporated materials results in better film quality. However, mixing of the various evaporated materials often results in the heaver atoms or molecules scattering the lighter atoms or molecules. Gas scattering reduces the amount of material deposited on the substrate and increases the amount of material deposited in the system. This leads to decreased deposition rate, increased debris generation, and reduced run-time. There is also substantial debris buildup on shielding nearby the transport rollers which can start to grow towards the substrate edges and begin to shadow the substrate, thereby contributing to poor coating uniformity.

Heretofore, the requirements of reducing debris buildup, extending run times and avoiding shadowing of substrates referred to above have not been fully met. In view of the foregoing, there is a need in the art for a solution that simultaneously solves all of these problems.

### CROSS-REFERENCE TO RELATED APPLICATION

Referring to the application data sheet filed herewith, this application claims a benefit of priority under 35 U.S.C. 119(e) from co-pending provisional patent application U.S. Ser. No. 63/161,033, filed Mar. 15, 2021, the entire contents of which are hereby expressly incorporated herein by reference for all purposes.

### SUMMARY

There is a need for the following embodiments of the present disclosure. Of course, the present disclosure is not limited to these embodiments.

According to an embodiment of the present disclosure, a process comprises: operating movable reactor shielding located in a vacuum deposition chamber comprising at least one of operating movable source debris shields and operating movable reactor zone debris shields.

According to another embodiment of the present disclosure, a machine comprises: movable reactor shielding located in a vacuum deposition chamber, the movable reactor shielding comprising at least one of movable source debris shields and movable reactor zone debris shields.

These, and other, embodiments of the present disclosure will be better appreciated and understood when considered in conjunction with the following description and the accompanying drawings. It should be understood, however, that the following description, while indicating various embodiments of the present disclosure and numerous specific details thereof, is given for the purpose of illustration and does not imply limitation. Many substitutions, modifications, additions and/or rearrangements may be made within the scope of embodiments of the present disclosure, and embodiments of the present disclosure include all such substitutions, modifications, additions and/or rearrangements.

### BRIEF DESCRIPTION OF THE DRAWINGS

The drawings accompanying and forming part of this specification are included to depict certain embodiments of the present disclosure. A clearer concept of the embodiments described in this application will be readily apparent by referring to the exemplary, and therefore nonlimiting, embodiments illustrated in the drawings. The described embodiments may be better understood by reference to one or more of these drawings in combination with the following description presented herein. It should be noted that the features illustrated in the drawings are not necessarily drawn to scale.

FIGS. 1A-1D are views of a machine in accordance with an embodiment of the present disclosure. FIG. 1A is an isometric view of an exemplary realization of a system with rolling reactor shielding. FIG. 1B is an elevation view of the exemplary realization of the system with the rolling reactor shielding. FIG. 1C is a plan view of the exemplary realization of the system with the rolling reactor shielding. FIG. 1D is a side view of the exemplary realization of the system with the rolling reactor shielding.

### DETAILED DESCRIPTION

Embodiments presented in the present disclosure and the various features and advantageous details thereof are explained more fully with reference to the nonlimiting embodiments that are illustrated in the accompanying drawings and detailed in the following description. Descriptions of well-known materials, techniques, components and equipment are omitted so as not to unnecessarily obscure the embodiments of the present disclosure in detail. It should be understood, however, that the detailed description and the specific examples are given by way of illustration only and not by way of limitation. Various substitutions, modifications, additions and/or rearrangements within the scope of the underlying inventive concept will become apparent to those skilled in the art from this disclosure.

The disclosure of this application is technically related to copending U.S. Ser. No. ______ (attorney docket number HST001), filed Mar. 15, 2021; U.S. Ser. No. ______ (attorney docket number HST002), filed Mar. 15, 2021; and U.S. Ser. No. ______ (attorney docket number HST003), filed Mar. 15, 2021.

In general, the context of an embodiment of the present disclosure can include manufacture of semiconductor alloys, superconductor alloys, or other multinary functional coatings. For example, the context of an embodiment of the present disclosure can include manufacture of the (Ag,Cu)(In,Ga)(S,Se) material system on substrates for solar photovoltaic modules.

The present innovation addresses the requirements referred to above by providing a process and hardware for replacing/refreshing the underneath and surrounding shields of the reactor environment of a vacuum deposition chamber without venting the vacuum chamber or substantially disturbing evaporation source operation. By restoring the cleanliness of the bottom source surfaces and other surrounding reactor shielding, falling detached particle contamination to the substrates is reduced and campaign length is substantially increased. Since evaporation sources often run at high temperatures, down-time to do system maintenance that is extremely time consuming, taking hours or even days just to cool the sources enough to vent the vacuum chamber to change the shielding is reduced and/or avoided. Therefore, increasing the time the sources can be run before physical maintenance is required greatly improves the system availability and directly results in greater solar panel production.

In typical evaporation reactors, the surfaces of the source and surrounding shields are rigidly mounted due to cost and ease of construction. However, in deposit-down or certain deposit-up evaporation reactors, coating buildup on these surfaces is a big problem. The novel features of the present invention relate to hardware or processes to refresh the (bottom) surfaces of the source and/or surrounding reactor shields without dramatically disturbing the thermal and vacuum environment of the source. In the present innovation, shields are designed so the surfaces with coating can be moved out of the reactor portion of the deposition chamber or otherwise cleaned in-place by flexing, vibrating, or thermally shocking those surfaces having coating buildup. In some cases, the debris will fall from the source and needs to either have room for it to accumulate around the transport system without causing an issue, or it needs to be collected on sacrificial glass or other material that is loaded into the system and then conveyed out of the system during the cleaning process. The debris can be effectively removed from the evaporation zone by the present innovation so it cannot build up inside the reactor portion of the deposition chamber.

1. An evaporation source(s) within a reactor zone(s).

2. A reactor zone(s) substantially enclosed by shields and/or evaporation source surfaces and/or chamber interior walls which contain the evaporated material inside of the vacuum deposition chamber(s).

3. Shields that are movable, rollable, or flexible so as to move the coated portion of the shields outside the enclosed reactor zone

4. In one embodiment, an apparatus that grabs the shields and pull them out of the debris accumulation area and replaces the shields with new ones. This could be done within the deposition chamber, or into a load lock chamber that is mounted to the side of the deposition chamber.

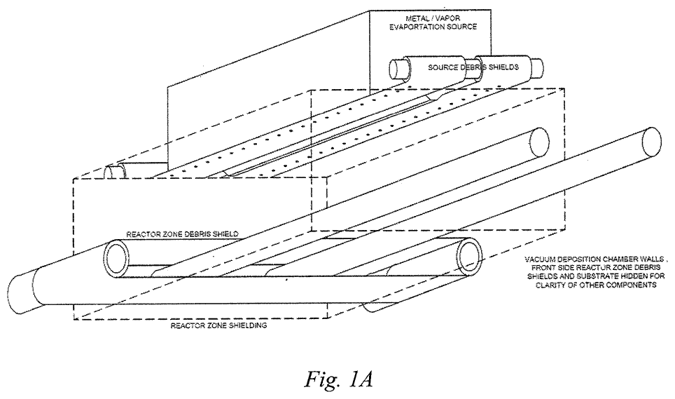

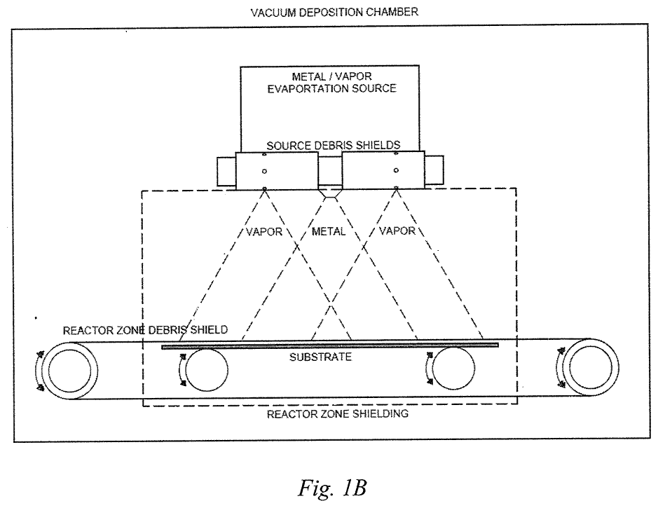

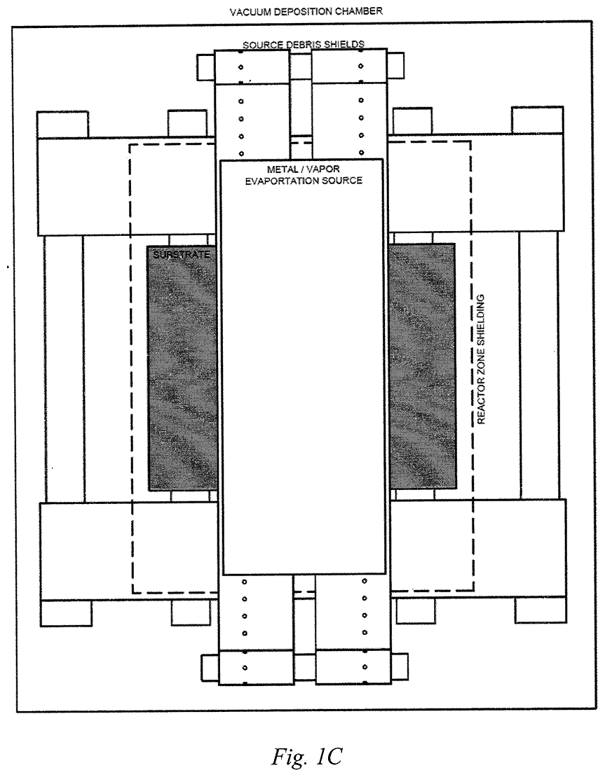

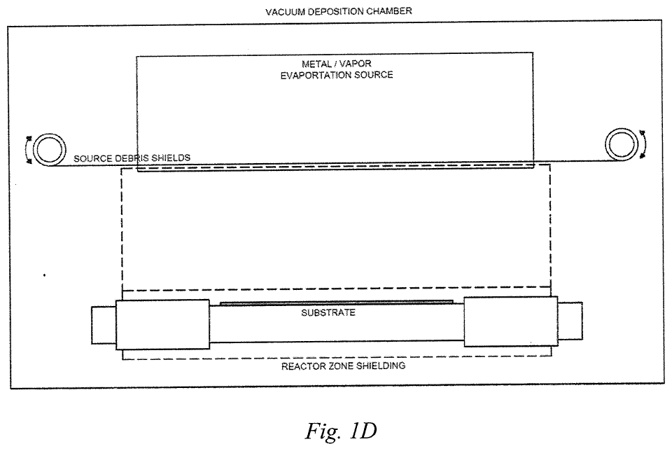

5. In another embodiment, as in FIG. 1, the bottom surface of the source(s) and other reactor zone shields are thin webs of flexible material that are rolled away from the area where debris accumulates on them. Rolling of the material would suffice to both replace the surface(s) and also to break the debris off of the web surface that is being rolled, thereby cleaning it.

6. In another embodiment, attachments to the shields that allow them to be flexed or shaken while in place so as to dislodge the built-up coating.

7. In another embodiment, the shields have heaters and/or cooling channels designed to locally change the temperature of the shield where the coating has built up. The change in surface and/or debris temperature will cause debris to fall off the shields and into the vacuum chamber.

8. In another embodiment, a dummy cleaning substrate(s) that has substantially different thermal characteristics than the normal substrate (Different reflectivity and/or temperature) is periodically conveyed through the system. The change in substrate temperature or reflectivity will change the shield surface temperatures without too much change to the interior evaporation source temperature(s). This will have the same effect of dislodging the coating as in 7 above.

An embodiment of the present disclosure can also be included in a kit-of-parts. The kit-of-parts can include some, or all, of the components that an embodiment of the present disclosure includes. The kit-of-parts can be an in-the-field retrofit kit-of-parts to improve existing systems that are capable of incorporating an embodiment of the present disclosure. The kit-of-parts can include software, firmware and/or hardware for carrying out an embodiment of the present disclosure. The kit-of-parts can also contain instructions for practicing an embodiment of the present disclosure. Unless otherwise specified, the components, software, firmware, hardware and/or instructions of the kit-of-parts can be the same as those used in an embodiment of the present disclosure.

An embodiment of the present disclosure can also utilize data processing methods that transform signals from sensors and/or transducers to machine control signals. For example, an embodiment of the present disclosure can be combined with instrumentation to obtain state variable information to actuate interconnected discrete hardware elements. For instance, an embodiment of the present disclosure can include the use of temperature data to control machine configuration and/or operational parameters.

### Practical Applications

A practical application of an embodiment of the present disclosure that has value within the technological arts is co-evaporation of thin film devices. Further, an embodiment of the present disclosure is useful in conjunction with co-evaporation of the (Ag,Cu)(In,Ga)(S,Se) material system (that is used for the purpose of generating electricity), or in conjunction with co-evaporation of super conductors (such as are used for the purpose of conducting electricity with no resistance), or the like. There are virtually innumerable uses for embodiments of the present disclosure, all of which need not be detailed here.

### Definitions

The term compound is intended to mean a substance formed when two or more chemical elements are chemically bonded together, the elements present in ratios with a limited range of variation and characteristic crystal structure. The term phase is intended to mean a limited range of compositions of a mixture of the elements (in a thermochemical system) throughout which the chemical potential of the mixture varies with composition, and which either changes discontinuously or remains constant outside of that range. The phrase cation content is intended to mean the percentage or relative amount of a given cation of interest (relative to total number of atoms) in a given volume or mass of interest. The selenium atoms are not cations, they are technically anions and cation content is normalized to the total number of atoms in the film per unity volume. The term absorber is intended to mean the photon absorbing portion of a photovoltaic device which can generate current in operation. Other parts of the cell also absorb light but if they cannot generate current this is called “parasitic absorption”. The term buffer is intended to mean the junction forming region of a photovoltaic. The term emitter is intended to mean the negative contact of an illuminated photovoltaic without current flow. The term amorphous transparent conductive layer is intended to mean a non-crystalline, substantially photon transparent, electronically conducting portion of a photovoltaic. The term back contact is intended to mean the contact of a photovoltaic on the side opposite the incident illumination. The term photovoltaic is intended to mean an article of manufacture for the generation of a voltage when radiant energy falls on the boundary between dissimilar substances (as two different semiconductors).

The term vapor distribution manifold is intended to mean the distribution manifold of a vapor (evaporation source) source. The term uniformly is intended to mean unvarying or deviating very little from a given and/or expected value (e.g, within 10% of). The term substantially is intended to mean largely but not necessarily wholly that which is specified. The term approximately is intended to mean at least close to a given value (e.g., within 10% of). The term generally is intended to mean at least approaching a given state. The term coupled is intended to mean connected, although not necessarily directly, and not necessarily mechanically. The term proximate, as used herein, is intended to mean close, near adjacent and/or coincident; and includes spatial situations where specified functions and/or results (if any) can be carried out and/or achieved. The term distal, as used herein, is intended to mean far, away, spaced apart from and/or non-coincident, and includes spatial situation where specified functions and/or results (if any) can be carried out and/or achieved. The term deploying is intended to mean designing, building, shipping, installing and/or operating.

The terms first or one, and the phrases at least a first or at least one, are intended to mean the singular or the plural unless it is clear from the intrinsic text of this document that it is meant otherwise. The terms second or another, and the phrases at least a second or at least another, are intended to mean the singular or the plural unless it is clear from the intrinsic text of this document that it is meant otherwise. Unless expressly stated to the contrary in the intrinsic text of this document, the term or is intended to mean an inclusive or and not an exclusive or. Specifically, a condition A or B is satisfied by any one of the following: A is true (or present) and B is false (or not present), A is false (or not present) and B is true (or present), and both A and B are true (or present). The terms a and/or an are employed for grammatical style and merely for convenience.

The term plurality is intended to mean two or more than two. The term any is intended to mean all applicable members of a set or at least a subset of all applicable members of the set. The phrase any integer derivable therein is intended to mean an integer between the corresponding numbers recited in the specification. The phrase any range derivable therein is intended to mean any range within such corresponding numbers. The term means, when followed by the term “for” is intended to mean hardware, firmware and/or software for achieving a result. The term step, when followed by the term “for” is intended to mean a (sub)method, (sub)process and/or (sub)routine for achieving the recited result. Unless otherwise defined, all technical and scientific terms used herein have the same meaning as commonly understood by one of ordinary skill in the art to which this present disclosure belongs. In case of conflict, the present specification, including definitions, will control.

The described embodiments and examples are illustrative only and not intended to be limiting. Although embodiments of the present disclosure can be implemented separately, embodiments of the present disclosure may be integrated into the system(s) with which they are associated. All the embodiments of the present disclosure disclosed herein can be made and used without undue experimentation in light of the disclosure. Embodiments of the present disclosure are not limited by theoretical statements (if any) recited herein. The individual steps of embodiments of the present disclosure need not be performed in the disclosed manner, or combined in the disclosed sequences, but may be performed in any and all manner and/or combined in any and all sequences. The individual components of embodiments of the present disclosure need not be formed in the disclosed shapes, or combined in the disclosed configurations, but could be provided in any and all shapes, and/or combined in any and all configurations. The individual components need not be fabricated from the disclosed materials, but could be fabricated from any and all suitable materials. Homologous replacements may be substituted for the substances described herein. Agents which are chemically related may be substituted for the agents described herein where the same or similar results would be achieved.

Various substitutions, modifications, additions and/or rearrangements of the features of embodiments of the present disclosure may be made without deviating from the scope of the underlying inventive concept. All the disclosed elements and features of each disclosed embodiment can be combined with, or substituted for, the disclosed elements and features of every other disclosed embodiment except where such elements or features are mutually exclusive. The scope of the underlying inventive concept as defined by the appended claims and their equivalents cover all such substitutions, modifications, additions and/or rearrangements.

The appended claims are not to be interpreted as including means-plus-function limitations, unless such a limitation is explicitly recited in a given claim using the phrase(s) “means for” or “mechanism for” or “step for”. Sub-generic embodiments of this disclosure are delineated by the appended independent claims and their equivalents. Specific embodiments of this disclosure are differentiated by the appended dependent claims and their equivalents.

What is claimed is:

1. A method, comprising
operating movable reactor shielding located in a vacuum deposition chamber comprising at least one of
operating movable source debris shields and
operating movable reactor zone debris shields.

2. The method of claim 1, wherein operating movable reactor shielding comprises operating movable source debris shields and operating movable reactor zone debris shields.

3. The method of claim 1, wherein operating movable reactor shielding comprises rolling movable reactor shielding

4. The method of claim 1, wherein operating movable reactor zone debris shields comprises rolling moving reactor zone debris shields.

5. The method of claim 1, wherein operating movable source debris shields comprise rolling movable source debris shields.

6. The method of claim 5, wherein the movable source debris shields define a longitudinal slot for flux emitted from a metal evaporation source.

7. The method of claim 5, wherein the movable source debris shields define apertures for flux emitted from a vapor distribution manifold.

8. The method of claim 1, wherein operating movable reactor shielding comprises cleaning in-place by at least one of flexing, vibrating and thermally shocking.

9. An apparatus for performing the method of claim 1.

10. An article of manufacture made in accordance with the method of claim 1.

11. An assembly, comprising an article of manufacture made in accordance with the method of claim 1.

12. A coating made in accordance with the method of claim 1.

13. An apparatus, comprising:
movable reactor shielding located in a vacuum deposition chamber, the movable reactor shielding comprising at least one of
movable source debris shields and
movable reactor zone debris shields.

14. The apparatus of claim 13, wherein the movable reactor shielding comprises movable source debris shields and movable reactor zone debris shields.

15. The apparatus of claim 13, wherein the movable reactor shielding comprises rolling reactor shielding

16. The apparatus of claim 13 wherein the movable reactor zone debris shields comprises rolling reactor zone debris shields.

17. The apparatus of claim 13, wherein the movable source debris shields comprises rolling source debris shields.

18. The apparatus of claim 17, wherein the rolling source debris shields define a longitudinal slot for flux emitted from a metal evaporation source.

19. The apparatus of claim 17, wherein the rolling source debris shields define apertures for flux emitted from a vapor distribution manifold.

20. The apparatus of claim 13, wherein the movable reactor shielding is cleaned in-place by at least one of flexing, vibrating and thermally shocking.

21. A deposition chamber comprising the apparatus of claim 13.

22. A coating made with the apparatus of claim 13.

23. A method for producing a coating which comprises utilizing the apparatus of claim 13.
